(19) United States
(12) Patent Application Publication
(10) Pub. No.: US 2026/0312581 A1
(43) Pub. Date: Oct. 8, 2026

(54) DISCHARGING OF A DAMPING CAPACITOR

(71) Applicant: ams-OSRAM AG, Premstaetten (AT)

(72) Inventors: Valerio PISATI, Bosnasco (IT); Juri CAMBIERI, Gleisdorf (AT); Carlo FIOCCHI, Belgioioso (PV) (IT); Oskar SCHALLMOSER, Ottobrunn (DE); Robert GEIGER, Kochel am See (DE)

(21) Appl. No.: 19/482,251

(22) PCT Filed: Oct. 7, 2024
(86) PCT No.: PCT/EP2024/078129

§ 371 Date: Nov. 7, 2025

(30) Foreign Application Priority Data
Oct. 19, 2023 (DE) 10 2023 128 693.5

(51) Int. Cl. H03K 17/0812; H02H 1/00; H02H 9/04

(52) U.S. Cl. CPC H03K 17/08122; H02H 1/0007; H02H 9/042

(57) ABSTRACT

The present disclosure relates to a circuit including: a supply terminal configured to receive a supply voltage; a driver circuit including: an input terminal coupled with the supply terminal to receive the supply voltage as input voltage; and a current source configured to draw current from the input terminal through a load coupled between the input terminal and ground, wherein the load comprises a series element; and a damping capacitor coupled in parallel with the input terminal and ground such that the damping capacitor is charged by the supply voltage; wherein the driver circuit further includes an overvoltage detection circuit configured to: determine a voltage value of the input voltage; and if the voltage value of the input voltage fulfills an overvoltage criterion, trigger a low current operation mode of the current source to allow a discharge of the damping capacitor through the series element.

### TECHNICAL FIELD

The present disclosure relates generally to a circuit configured to implement a scheme for discharging a damping capacitor in case of an overvoltage condition, and to methods thereof (e.g., a method of discharging a damping capacitor in case of an overvoltage condition)

### BACKGROUND

In general, protection of electronic circuits from events that may deteriorate, damage, or even destroy their components is of utmost importance for preventing the risk of failures of electronic devices. In particular, unexpected increases in supply voltage (so-called, “voltage surges”) may cause an electronic circuit to receive a voltage that greatly exceeds the nominal specified voltage range for the circuit, thus potentially damaging or breaking sensitive components. The occurrence of voltage surges may be a problem of particular relevance in the automotive context, e.g. for electric vehicles, in which the battery unit powers up several electronic components and circuits. Various surge protection components have been developed, which may include variable resistors, transient voltage suppressors, damping capacitors, and the like. In general, a surge protection component absorbs or diverts the excess electrical energy, thus protecting the electronic circuit from sudden peaks in the supply voltage. Thus, improvements in the field of surge protection components for protecting electronic circuits may be of particular relevance for the further advancements of several technologies.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A shows a circuit configured to implement a scheme for discharging a damping capacitor, in a schematic representation according to various aspects;

FIG. 1B shows the circuit of FIG. 1A further including a temperature detection circuit, in a schematic representation according to various aspects;

FIG. 1C shows the circuit of FIG. 1A further including a control circuit, in a schematic representation according to various aspects;

FIG. 2 shows an exemplary realization of a current source of the circuit, in a schematic representation according to various aspects;

FIG. 3A and FIG. 3B show exemplary realizations of the circuit of FIG. 1A, in a schematic representation according to various aspects;

FIG. 4 shows a schematic flow diagram of a method of discharging a damping capacitor, according to various aspects; and

FIG. 5 shows a schematic flow diagram of a method of programming a circuit for implementing a scheme for discharging a damping capacitor, according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a circuit, a driver circuit, an overvoltage detection circuit, a load, a series element). However, it is understood that aspects described in connection with methods may similarly apply to the devices, and vice versa.

In general, electronic circuits may include surge protection components to absorb or divert excess electrical energy, which may be delivered to the electronic circuit in case of a surge of supply voltage. Surge protection components may be of various types, e.g. including high voltage transistors, voltage-dependent resistors (VDR), transient voltage suppressors (TVS), damping capacitors, and the like. In this context, damping capacitors offer several benefits, e.g. in terms of a relatively low cost, a relatively low surface utilization, and a high tunability to the specific requirements of a certain circuit. Damping capacitors may be usually disposed at the input terminal of an electronic circuit to reduce noise and provide protection against voltage spikes.

Unexpected surges in supply voltage may occur in many different scenarios and due to many different causes, so that surge protection plays a role in a variety of different applications. Of particular interest is the protection of electronic circuits and components in a vehicle (e.g., in an electric car), which is a type of environment in which sudden spikes in supply voltage may cause the malfunction of components critical for the driver's safety. In a vehicle, a voltage surge may be the result of a load being turned off, and of the regulator being slow in adapting the generated power, so that there is an excess of power being delivered to the other (still on) electronic circuits and components. A voltage surge in a vehicle may bring the supply voltage to rather high values, e.g. 120 V, well above the safe operating range of electronic circuits and components commonly employed to implement various functionalities of the vehicle. A voltage surge may thus cause an overvoltage of the electronic circuit.

In a conventional configuration, an electronic circuit may include a damping capacitor and other surge protection components coupled with the input terminal at which the electronic circuit receives a supply voltage. Furthermore, the electronic circuit may be configured to implement a surge protection function according to which the circuit is turned off in case of an overvoltage condition at the input terminal, e.g. triggered by the voltage increase, and/or in case of a corresponding increase of the operating temperature of the circuit. In case of a voltage surge, the excess energy is absorbed by the surge protection components and the circuit is turned off to prevent the risk of damages to the circuit.

Aspects of the present disclosure may be based on the realization that in case of a voltage surge the damping capacitor becomes charged at a high voltage, so that even after the voltage surge has finished and the voltage returned back to a safe operating range, a high voltage remains at the input terminal of the electronic circuit. This behavior may occur in case a discharge of the capacitor towards the supply side is prevented by the configuration of the supply source. This may occur, for example, if the supply source is asymmetric, i.e. if the supply source has the capability of supplying current but has limited capability for sinking current. Illustratively, the supply source may allow flow of current in the forward direction from the supply source towards the electronic circuit (and the capacitor), but may prevent the flow of current in the reverse direction from the electronic circuit (and the capacitor) towards the supply source.

This situation may occur in a variety of configurations. As a relevant example, the discharge of the capacitor towards the supply side may be prevented by a filter element (e.g. a diode) that provides reverse protection by blocking the negative portion of the supply voltage. The filter element may allow flow of current in the forward direction (from supply source to capacitor) and prevent the flow of current in the reverse direction (from capacitor to supply source). As another example, the supply source may be configured such that the supply source may supply a high amount of current but may absorb (in other words, sink) only a small amount of current. Illustratively, the supply source may supply a greater amount of current compared to the amount of current that the supply source may absorb. For example, this may be the case for a low-dropout regulator.

Illustratively, in the depicted scenario, the increase in the supply voltage may charge the damping capacitor, and the damping capacitor may remain charged for a certain period of time even after the supply voltage decreased back to its intended voltage range. The capacitor remains charged because its discharge towards the supply side is prevented by the configuration of the supply source (e.g., by the presence of a diode), and in a conventional system the discharge of the capacitor at the circuit side is slow because in case of an overvoltage the electronic circuit is turned off and draws almost no current.

In this situation, the electronic circuit may thus still see a high voltage at the input terminal despite the fact that the supply voltage returned to a safe range. The circuit may thus refrain from resuming its operation (illustratively, from turning back on) due to the high voltage provided by the charged capacitor. The high voltage at the input terminal may thus cause the electronic circuit to remain turned off for an unnecessarily long period of time, illustratively the period of time it takes for the damping capacitor to discharge.

This undesired behavior of the electronic circuit may be particularly evident in case the surge of the supply voltage takes the form of a sequence of voltage pulses. Each voltage pulse may have a voltage value (e.g., at the peak) causing an overvoltage condition of the electronic circuit and thus causing the electronic circuit to turn off. Positive voltage peaks in bursts (surge pulses) load the damping capacitor (also referred to herein as filtering capacitor or smoothing capacitor) at a voltage level higher than the operational one, especially if there is a reverse diode in series, thus stressing or causing the chip protections to intervene and put in shutdown the analog sections and the external load. As mentioned, in certain circuit configurations the discharge of the damping capacitor may be slow such that the damping capacitor remains charged at a high voltage during the interval between consecutive voltage pulses. Thus, in this scenario the electronic circuit remains off for the whole duration of the sequence of voltage pulses, even though it would be possible to safely operate the circuit in the interval between voltage pulses, during which the supply voltage has a voltage value in a safe operating range.

Aspects of the present disclosure may be related to a strategy to provide a rapid discharge of a damping capacitor, e.g. in case of a voltage surge, thus ensuring that an electronic circuit may resume its intended operation in a fast and efficient manner. In particular, the present disclosure may be based on the realization that it may be possible to discharge the damping capacitor using current that is already utilized in the electronic circuit, e.g. the current flowing through a load of the electronic circuit, e.g. a load that includes an internal series element and/or external series element. Illustratively, the proposed strategy may be based on the realization that maintaining a (reduced) current flow through the load of the electronic circuit (e.g., through the internal and/or external series element) provides a path for the discharge of the damping capacitor.

By way of illustration, the proposed approach may be based on realization that rather than completely turning off the electronic circuit (and the drawing of current through the series element(s)), a current source of the electronic circuit may be maintained active to draw current from the input terminal of the circuit, thus providing a discharge path to enable a rapid discharge of the damping capacitor. The discharge of the damping capacitor may cause the electronic circuit to see a lower voltage at the input terminal, thus allowing the electronic circuit to resume its operation in a faster manner. The proposed approach allows to discharge the damping capacitor quickly and without damaging the circuit due to prolonged overvoltage and higher power dissipation and avoiding over-temperature conditions.

According to various aspects, a circuit may include: a supply terminal configured to receive a supply voltage; a driver circuit including an input terminal coupled with the supply terminal to receive the supply voltage as input voltage for powering an operation of the driver circuit; and a damping capacitor coupled in parallel with the input terminal and ground such that the damping capacitor is charged by the supply voltage; wherein the driver circuit further includes a current source configured to draw current from the input terminal through a load coupled between the input terminal and ground, wherein the load includes a series element coupled in series between the input terminal and ground, and an overvoltage detection circuit configured to: determine a voltage value of the input voltage at the input terminal; and if the voltage value of the input voltage fulfills an overvoltage criterion, trigger a low current operation mode of the current source to allow a discharge of the damping capacitor through the load, e.g. through the series element.

In general, the circuit may be configured such that, in operation, a discharge of the damping capacitor towards the supply terminal is prevented. For example, the supply terminal may be coupled with a supply source configured to supply a greater amount of current compared to an amount of current that the supply source is capable of absorbing. As another example, the circuit may further include a filter element coupled between the supply terminal and the input terminal and configured to block a negative portion of the supply voltage (and accordingly a flow of current in the reverse direction from the capacitor towards the supply terminal and supply source).

The proposed configuration may be implemented without introducing additional components, such as high voltage transistors. In principle a high voltage NMOS transistor, where NMOS is an acronym for N-type metal oxide semiconductor, may be added in parallel to the damping capacitor to allow a discharge of the damping capacitor, e.g. between consecutive peaks in a sequence of (over)voltage pulses. Illustratively, TVS and VDR clamps used to reduce the maximum value of the voltage peak, or a diode used to clamp negative signal residues, are not capable of discharging the filtering capacity in a rapid manner, e.g. during time between one peak and another, so that an active discrete component such as a high voltage NMOS may be introduced.

However, such type of active discrete component is rather expensive and occupies a large silicon area on the chip, thus making it an unattractive solution, especially considering the constant trend towards cost reduction and miniaturization of electronic circuits. Furthermore, the use of clamp structures and the active clamp (like NMOS) inside the chip increases the power dissipation. In contrast thereto, the proposed scheme for a rapid discharge of the damping capacitor may be implemented with components already present in the circuit, e.g. a current source, series element(s), etc. Thus, the proposed configuration may be implemented at a lower cost and with a lower footprint compared to alternative solution that rely on expensive active discrete components.

The configuration described therein has thus an applicative advantage, in that no extra external components are needed, e.g. to avoid the negative effects of the surge pulses present in a battery power supply. Furthermore, the proposed type of protection may be easily trimmable both in the intervention voltage level and in the current level, thus allowing to adjust the discharge current value and the discharge time. The programmability of the various parameter influencing the discharge of the damping capacitor ensures great flexibility in setting up the circuit, to adjust the protection functionality to the specific context in which the electronic circuit should operate.

The proposed approach may be of particular relevance for electronic circuits for use in a vehicle, e.g. in an electric car, which is an application scenario in which sequences of voltage pulses at a high voltage may occur more often than in other types of applications. The proposed strategy for a rapid discharge of a damping capacitor may thus be particularly suitable to ensure a robust and reliable operation of the electronic circuits of a vehicle. Thus, in the following particular reference may be made to the integration of a circuit configured as proposed herein in a vehicle, e.g. for coupling with a battery unit of the vehicle as source of supply voltage. It is however understood that the applications of a circuit configured as described herein are not limited to the automotive context, and the proposed circuit may be for use also in any suitable type of environments or device in which surge protection may be of relevance.

Furthermore, the proposed approach may be of particular relevance for implementation in an electronic for the driving of light emitting elements, e.g. light emitting diodes. The proposed strategy for a rapid discharge of a damping capacitor may ensure that the light emitting elements (e.g., in the headlight of a vehicle) are turned off for a short(er) period of time in case of an overvoltage, thus providing a more stable and reliable operation, which may provide an enhanced safety in the automotive context. Thus, in the following particular reference may be made to a configuration in which the external series element driven by a driver circuit includes one or more light emitting elements. It is however understood that the external series element of the proposed circuit is not limited to light emitting elements, and the external series element of the proposed circuit may include any suitable type of component through which current may be drawn to allow the discharge of the damping capacitor in case of overvoltage.

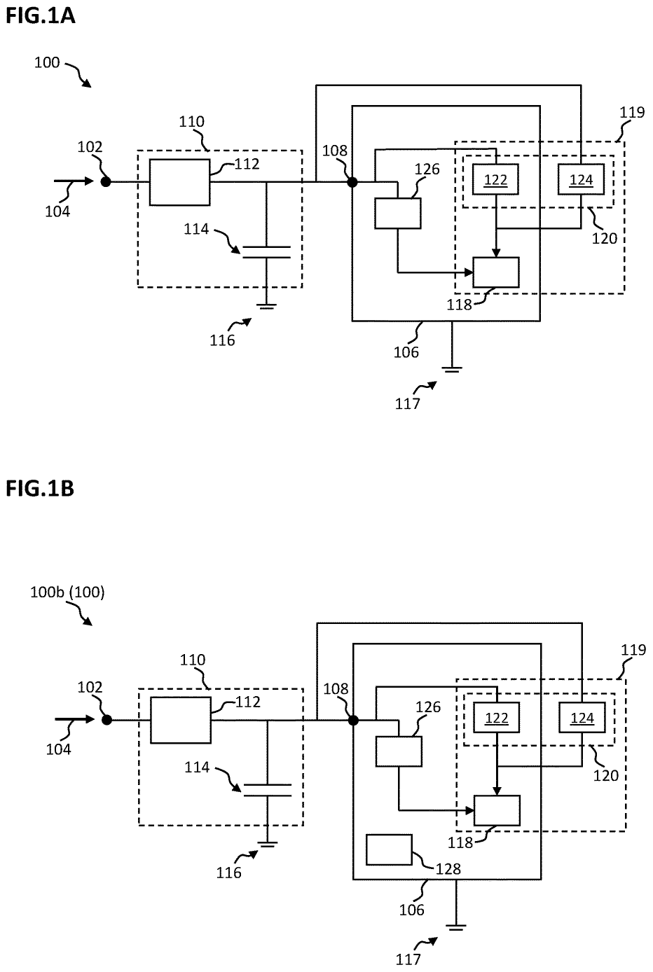

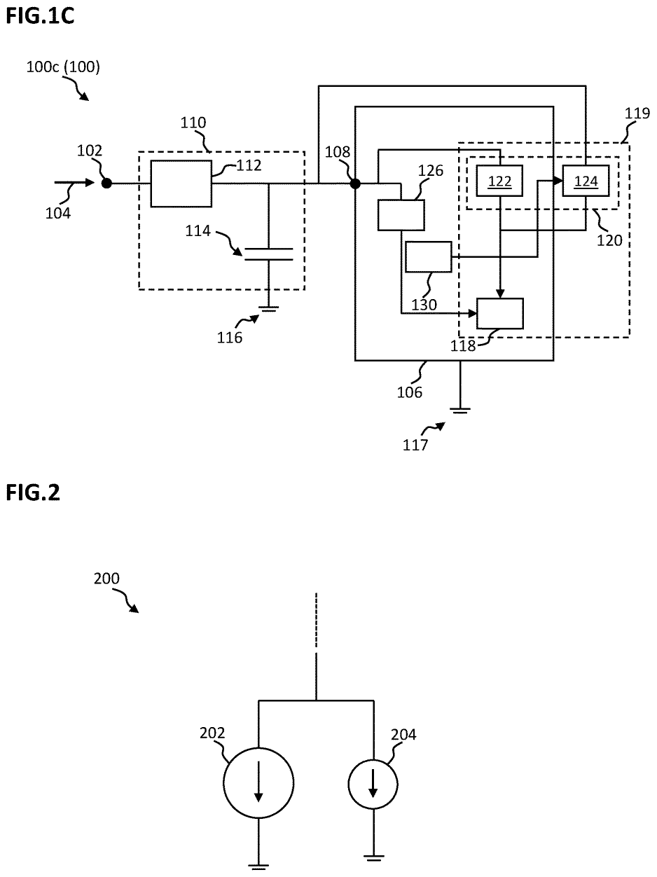

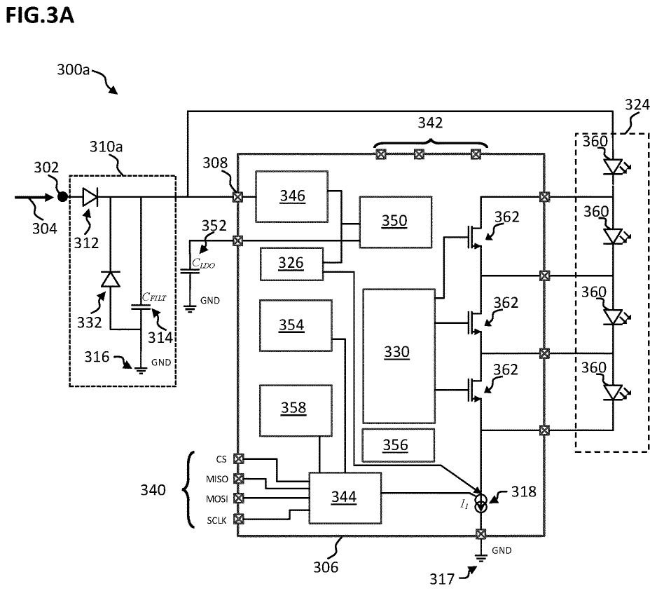

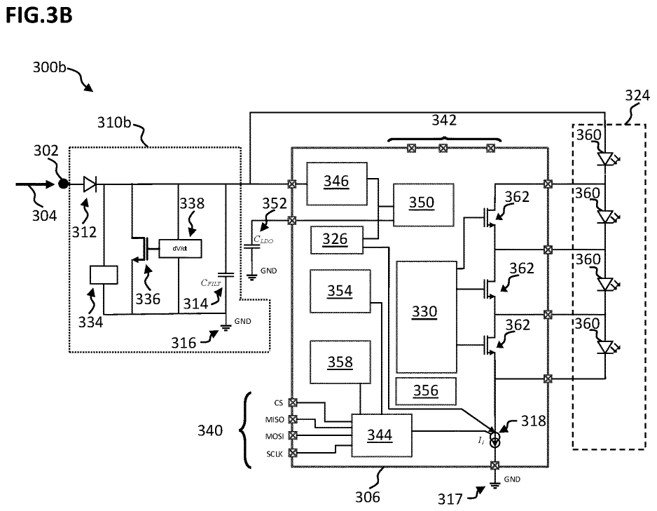

FIG. 1A shows an electronic circuit 100 configured to implement an adapted scheme for causing a discharge of a damping capacitor, in a schematic representation according to various aspects. As an exemplary use case scenario, the electronic circuit 100 may be for use in a vehicle. For example, a vehicle, such as an electric car, may include one or more electronic circuits configured as the electronic circuit 100. In the following, the electronic circuit 100 may be referred to simply as circuit 100. It is understood that the representation of the circuit 100 in FIG. 1A may be simplified for the purpose of illustration, and the circuit 100 may include additional components with respect to those shown (see also FIG. 3A and FIG. 3B).

The circuit 100 may include a supply terminal 102 configured to receive a supply voltage 104. The supply terminal 102 may be configured to be coupled with a supply source, e.g. a constant voltage source, that generates and delivers the supply voltage 104. For example, considering the integration of the circuit 100 in a vehicle, the supply terminal 102 may be coupled with a battery unit of the vehicle, and may receive the supply voltage 104 from the battery unit. A supply voltage from the battery unit may also be referred to herein as battery voltage, V_{BAT}. In some aspects, the circuit 100 may further include a supply source coupled with the supply terminal 102, e.g. a battery unit coupled with the supply terminal 102.

The circuit 100 may further include a driver circuit 106 coupled with the supply terminal 102 to receive the supply voltage 104. The driver circuit 106 may in general be an electronic circuit configured to implement a certain functionality, for example the driver circuit 106 may be a circuit configured to drive one or more electronic elements coupled with the driver circuit 106, as discussed in further detail below. It is however understood that the driver circuit 106 is not limited to a circuit that drives a component but may be in general any suitable circuit in which the scheme proposed herein may be implemented.

In some aspects, the driver circuit 106 may be an integrated circuit, illustratively the various components of the driver circuit 106 may be integrated on the same substrate, e.g. on a printed circuit board (PCB) substrate. The driver circuit 106 may also be referred to as integrated circuit device. The representation of the driver circuit 106 in FIG. 1A may be simplified for the purpose of illustration, and the driver circuit 106 may include additional components with respect to those shown (see also FIG. 3A and FIG. 3B). As further exemplary components, the driver circuit 106 may include a digital processing circuit, a power management circuit, a control circuit (see FIG. 1C), a temperature detection circuit (see FIG. 1B), and the like.

The driver circuit 106 may include an input terminal 108 coupled with the supply terminal 102 to receive the supply voltage 104 as input voltage for powering an operation of the driver circuit 106. In various aspects, the input terminal 108 may be indirectly coupled with the supply terminal 102, e.g. over a protection circuit 110 that will be described in further detail below. In this configuration, the input voltage at the input terminal 108 may be the supply voltage 104 as output from the protection circuit 110. Depending on the type of components of the protection circuit 110, one or more properties of the input voltage at the input terminal 108 (e.g., an amplitude, a sign, etc.) may be different from corresponding properties of the supply voltage 104 at the supply terminal 102. Illustratively, the input voltage at the input terminal 108 may in general have a behavior corresponding to the behavior of the supply voltage 104, but the input voltage may differ from the supply voltage 104 in view of the functionality of the components of the protection circuit 110.

In general, the protection circuit 110 may include one or more components to protect the driver circuit 106 from an undesired (and unexpected) behavior of the supply voltage 104. In an exemplary, simple configuration the protection circuit 110 may include a filter element 112 coupled between the supply terminal 102 and the input terminal 108, and a damping capacitor 114 coupled in parallel with the input terminal 108 and ground. It is however understood that, in principle, the protection circuit 110 may include additional components to further enhance the protection of the driver circuit 104. Further exemplary protection components, e.g. for surge protection, will be described in further detail below. It is also understood that, in principle, the protection circuit 110 may include only the damping capacitor 114 (without the filter element 112).

The filter element 112 may be configured to block a negative portion of the supply voltage 104. Illustratively, the filter element 112 may be configured to receive the supply voltage 104 from the supply terminal 102, e.g. a supply voltage 104 having positive and negative values, and to deliver an output voltage including only the positive portion of the supply voltage 104. The voltage at the output of the filter element 112 may thus include only positive values, e.g. only values equal to or greater than 0 V considering 0 V as reference voltage for the circuit 100. The filter element 112 may thus be connected in series with the supply terminal 102 and may be configured to provide reverse voltage protection by preventing negative (reversed) voltage to reach the input terminal 108 of the driver circuit 106. Illustratively, the filter element 112 may have a rectifying function on the supply voltage 104.

The filter element 112 may be realized in any suitable manner, e.g. as an individual component or as a combination of multiple components. As an exemplary configuration, the filter element 112 may be or include a diode, e.g. a Schottky diode. The diode may allow power (e.g., voltage) to reach the driver circuit 106 only when the diode is forward biased (by a positive supply voltage 104 or a positive portion of the supply voltage 104), and block the voltage in case of reverse bias. A diode may provide a simple and cost-effective reverse voltage protection. It is however understood that, in principle, the filter element 112 may be realized in a different manner, e.g. the filter element 112 may include a metal-oxide-semiconductor field-effect transistor (MOSFET), or an oRing controller in combination with a power MOSFET, as other examples.

The damping capacitor 114 may in general be configured to protect the driver circuit 106 from spikes in the supply voltage 104, e.g. spikes in the positive portion of the supply voltage 104 as output by the filter element 112. Illustratively, the damping capacitor 114 may be coupled in parallel with the input terminal 108 and a ground terminal 116, such that the supply voltage 104 at the supply terminal 102 may charge the damping capacitor 114, e.g. the positive portion of the supply voltage 104 as output by the filter element 112 may charge the damping capacitor 114. Illustratively, the voltage difference between the terminal at which the damping capacitor 114 sees the supply voltage 104 and the ground terminal 116 causes a current flow that charges the damping capacitor 114.

As generally known in the art, a damping capacitor (e.g., the damping capacitor 114) may absorb excess energy, thus preventing the excess energy to reach and damage other components (e.g., the driver circuit 106). The damping capacitor may reduce the amplitude of a high-frequency signal, e.g. a high-frequency supply voltage.

The ground terminal 116 (and the ground terminal 117) may be a reference terminal at which a reference voltage for the circuit 100 is provided. The term “reference voltage” may be used herein to denote a base voltage for the circuit 100. In some aspects, the reference voltage may be also referred to as ground (GND) voltage, ground potential, virtual ground voltage, or zero volts (0 V). In an exemplary configuration the reference voltage may be 0 V, but the aspects described herein may apply in principle to any suitable value for the reference voltage.

The damping capacitor 114 may have any suitable configuration to implement the desired function, e.g. as a single component or as a combination of a plurality of components. For example, the damping capacitor 114 may be configured as a film capacitor, e.g. including a polymer as dielectric material, such as polyester, polypropylene or polycarbonate. As another example, the damping capacitor 114 may be configured as a ceramic capacitor including a ceramic material as dielectric. As a further example, the damping capacitor 114 may be configured as a tantalum capacitor including tantalum as dielectric material.

The properties of the damping capacitor 114, e.g. in terms of size, capacitance, and the like, may be adapted depending on fabrication constraints and depending on the intended operation of the circuit 100. For example, the capacitance of the damping capacitor 114 may be selected based on the frequency range of the circuit 100. Only as a numerical example, the damping capacitor 114 may have a capacitance in the range from 50 nF (nanofarad) to 500 μF (microfarad), for example in the range from 100 nF to 300 μF, for example a capacitance of about 220 nF.

In an exemplary configuration, the damping capacitor 114 may include a plurality of capacitors connected in series with one another. Illustratively, the damping capacitor 114 may be realized as a plurality of capacitors, so that in case one of the capacitors behaves as a short circuit, the other capacitors may still provide protection to the driver circuit 106. Such configuration may be of particular relevance as a safety feature in the automotive context, to ensure a safe and reliable operation of the circuit 100. The damping capacitor 114 may include any suitable number of series-connected capacitors, e.g. two in a simple and cost-effective configuration, or more than two, e.g. three, four, five, etc.

Considering a diode as filter element 112, the diode and the damping capacitor 114 may act as a peak detector. In case of an oscillating waveform of the supply voltage 104, the diode allows the positive portion (the positive cycles) of the supply voltage 104 to pass through and charge the damping capacitor 114 to the peak voltage of the waveform. When the waveform falls below the peak value stored in the damping capacitor 114, the diode is reverse biased and blocks the current flow from the damping capacitor 114 back to the supply terminal 102 (and supply source). The damping capacitor 114 may thus be isolated and store (illustratively, memorize) the peak value of the waveform of the supply voltage 104, even when the waveform drops (e.g., back to zero).

As mentioned above, aspects of the present disclosure may be based on the realization that in case of a voltage surge of the supply voltage 104, the fact that the damping capacitor 114 remains charged at the peak value of the waveform of the supply voltage 104 may lead to unnecessarily prolonged “off-time” of the driver circuit 106.

As discussed, the damping capacitor 114 may remain charged in a scenario in which there is limited possibility for a current to flow away from the capacitor. In general, the circuit 100 may be configured such that, in operation, the discharge of the damping capacitor 114 towards the supply terminal 102 is limited or prevented. In the exemplary configuration in FIG. 1A, the filter element 112 (e.g., the diode) may limit the discharge of the damping capacitor 114 by preventing the current flow in the reverse direction towards the supply terminal 102. In another exemplary configuration, the circuit 100 may include or may be coupled with a supply source (at the supply terminal 102) that limits or prevents current flow towards the supply source. The supply source may be an asymmetric supply source configured to supply current at a first current value and to absorb current at a second current value, and the second current value may be (much) lower than the first current value, for example at least 5 times lower, at least 10 times lower, or at least 20 times lower. In this configuration, the damping capacitor 114 may have a discharge path only towards the circuit side, i.e. towards the driver circuit 106.

In case of a voltage surge, the supply voltage 104 may have a voltage value greater than an operational voltage of the driver circuit 106, illustratively the maximum voltage rated for the operation of the driver circuit 106. For example, in case of a sequence of pulses, the voltage value of the pulses may be greater than the operational voltage of the driver circuit 106. At least the peak voltage of the pulses may be greater than the operational voltage of the driver circuit 106, or the voltage of the pulses may be greater than the operational voltage also prior to reaching the peak. The operational voltage of the driver circuit 106 may be a voltage or voltage range in which the driver circuit 106 may operate without incurring in the risk of damaging or breaking the components of the driver circuit 106. In case of a voltage surge, the supply voltage 104 may thus have or assume voltage values outside of the safe operating range of the driver circuit 106.

In general, the driver circuit 106 may be configured to implement protection mechanisms to turn off (in other words, shut down) the driver circuit 106 in case of a surge of the supply voltage 104. As long as the driver circuit 106 receives an input voltage at the input terminal 108 greater than the rated operational voltage, the driver circuit 106 may refrain from turning on again. However, in a conventional configuration the damping capacitor 114 may have a relatively slow discharge, e.g. due to the fact that the driver circuit 106 is off and there is no path for the current to flow away rapidly from the damping capacitor 114. Thus, in a conventional configuration the damping capacitor 114 retains a voltage value greater than the operational voltage of the driver circuit 106 for a relatively long time, and such voltage is seen at the input terminal 108 thus preventing the driver circuit 106 from turning on again.

Aspects of the present disclosure may be based on the realization that the current paths used during a normal operation of the circuit 100 may be exploited to allow a quick discharge of the damping capacitor 114 in case of a voltage surge of the supply voltage 104. The quick discharge of the damping capacitor 114 ensures that the input voltage at the input terminal 108 returns to a voltage value in the operational range of the driver circuit 106 in a rapid manner, thus allowing the driver circuit 106 to resume its operation.

The driver circuit 106 may include a current source 118 configured to generate current. In a preferred configuration the current source 118 may be configured to draw current from the input terminal 108 through a load 119 coupled between the input terminal 108 and ground 117. As shown in FIG. 1A, the load 119 may include a series element 120, e.g. one or more series elements 120. The series elements 120 may be coupled in series between the input terminal 108 and ground 117. The current source 118 may illustratively be configured to generate current by causing current to be drawn from the input terminal 108 and to flow through the series element 120 towards ground 117. Illustratively, the current source 118 may be coupled with the input terminal 108 through the series element 120, and may cause or induce a current flow from the input terminal 108 through the series element 120 by drawing current from the input terminal 108.

The load 119 may thus include the series element(s) 120 coupled in series with the current source 118. Illustratively, the current source 118 may be considered part of the load 119 that defines a path from the input terminal 108 to ground 117. The current source 118 may determine the current drawn through the load 119, and the series element(s) 120 may define the path through which the current flows from the input terminal 108 to ground 117 (illustratively, from the supply to ground).

The driver circuit 106 may further include an overvoltage detection circuit 126 configured to determine (e.g., detect, measure) a voltage value of the input voltage at the input terminal 108. Illustratively, the overvoltage detection circuit 126 may be configured to monitor the input voltage to detect the occurrence of an overvoltage condition. An overvoltage condition may include the voltage value of the input voltage at the input terminal 108 being greater than the rated operational voltage of the driver circuit 106, e.g. the voltage value of the input voltage at the input terminal 108 being outside of the nominal operational voltage range of the driver circuit 106.

The overvoltage detection circuit 126 may be further configured to trigger a low current operation mode of the current source 118 if the voltage value of the input voltage fulfills an overvoltage criterion to allow a discharge of the damping capacitor 114 through the series element 120. Illustratively, if the overvoltage detection circuit 126 detects an overvoltage at the input terminal 108, the overvoltage detection circuit 126 may control the current source 118 to enter a low current operation mode (described below in further detail) to allow a flow of current from the damping capacitor 114 through the load 119, e.g. through the series element(s) 120. The low current operation mode may thus cause a discharge of the damping capacitor 114. In the low current operation mode the current source 118 may illustratively act as a sink to allow a discharge of the capacitor 114 through the series element(s) 120 (and through the current source 118) towards ground 117.

By way of illustration, the proposed approach may thus be based on exploiting the already available current source 118 and current path through the series element 120 to allow the damping capacitor 114 to discharge in a rapid manner, thus allowing the driver circuit 106 to quickly exit the overvoltage condition. The discharge of the damping capacitor 114 will reduce the input voltage at the input terminal 108, thus allowing the driver circuit 106 to resume its intended operation.

The series element 120 through which current may be drawn may be any suitable element coupled in series between the input terminal 108 and ground, and through which the current source 118 may cause a flow of current by drawing the current from the input terminal 108. As shown in FIG. 1A, the series element may include an internal series element 122 of the driver circuit 106 and/or an external series element 124 of the driver circuit. Illustratively, the proposed approach may be applied by causing a flow of current through a (first) series element 122 disposed internally to the driver circuit 106, e.g. a series element integrated in the integrated driver circuit 106, and/or by causing a flow of current through a (second) series element 124 disposed externally to the driver circuit 106. The term “series element” or “one or more series elements” may thus be used herein to indicate collectively the internal series element 122 and the external series element 124, and in general to denote a component capable of sustaining a current flow even in condition of overvoltage and of discharging its current towards ground.

The internal series element 122 may be or include any suitable internal component of the driver circuit 106 capable of conducting current even in case of overvoltage. The internal series element 122 may be coupled with the input terminal 108 and with the current source 118 (and to ground 117). In some aspects, the internal series element 122 may be a dedicated component in the driver circuit 106, illustratively a component that does not carry out any other functionality other than allowing a current flow through it in case of an overvoltage. In other aspects, the internal series element 122 may be a component of the driver circuit 106 that carries out a certain functionality of the driver circuit 106 and is additionally used to draw current through it in case of an overvoltage. This second configuration may provide a cost- and space-efficient approach by reusing components already present in the circuit 100. As an example, the internal series element 122 may be or include one or more transistors (see also FIG. 3A).

The external series element 124 may be or include any suitable external component driven by the driver circuit 106, and capable of conducting current even in case of overvoltage. In general, the external series element may be coupled with the driver circuit 106, e.g. with the current source 118, and with the input terminal 108 (and with ground 117 over the current source 118). In some aspects, the external series element 124 may be in parallel with the internal series element 122. In some aspects, the external series element 124 may be a dedicated component for the discharge of the damping capacitor 114, illustratively a component that does not carry out any other functionality other than allowing a current flow through it in case of an overvoltage. In other aspects, the external series element 124 may be a component that carries out a certain functionality and is additionally used to draw current through it in case of an overvoltage. This second configuration may provide a cost- and space-efficient approach by reusing components already present in the circuit 100.

In principle, the external series element 124 may be any suitable electronic component, e.g. any suitable electronic component that the driver circuit 106 may drive (and control, as discussed in further detail below). In a preferred configuration the external series element 124 may include one or more light emitting elements, e.g. a plurality of light emitting elements, connected in series with one another. Aspects of the present disclosure may be based on the realization that the proposed approach may be of particular interest in the context of light emitting devices, e.g. for use in a vehicle, for example in the headlight of a vehicle or for the internal illumination of the vehicle. The external series element 124 may include any suitable number of light emitting elements, e.g. one, two, three, four, five, ten, or more than ten.

In principle, the light emitting elements may be of any suitable type. Considering the context of integrated circuits, the light emitting elements may be or include light emitting diodes (LEDs), e.g. the plurality of light emitting elements may include at least one light emitting diode. LEDs may be particularly suitable to allow a current flow even in case of an overvoltage condition. Illustratively, a LED may have a certain forward voltage, e.g. in the range from 1.8 V to 3.8 V depending on the color of the LED, but a LED may operate without suffering catastrophic damages even at higher voltages. As another example, the light emitting elements may be or include laser diodes, e.g. edge emitting laser diodes or vertical cavity surface emitting laser diodes.

The light emitting elements (e.g., the LEDs) may be configured to emit light having a predefined wavelength, for example in the visible range (e.g., from about 380 nm to about 700 nm), infrared and/or near-infrared range (e.g., in the range from about 700 nm to about 5000 nm), or ultraviolet range (e.g., from about 100 nm to about 400 nm). In some aspects, the light emitting elements may be configured to emit light in different wavelength ranges. For example a first light emitting element may be configured to emit light in a first wavelength range (e.g., a first color, for example blue), a second light emitting element may be configured to emit light in a second wavelength range (e.g., a second color, for example red), and a third light emitting element may be configured to emit light in a third wavelength range (e.g., a third color, for example green), etc.

The operation of the overvoltage detection circuit 126 and the low current operation mode of the current source 118 will now be described in further detail.

In principle, the overvoltage detection circuit 126 may determine the occurrence of an overvoltage condition in any suitable manner. Illustratively, any suitable overvoltage criterion may be considered for the input voltage to identify an overvoltage condition. In a preferred configuration, which may be implemented in a simple manner, to determine whether the voltage value of the input voltage fulfills the overvoltage criterion, the overvoltage detection circuit 126 may be configured to compare the voltage value of the input voltage with a predefined threshold voltage value.

In this configuration, the overvoltage detection circuit 126 may include a comparator (e.g., implemented as operational amplifier) configured to receive the input voltage at a first comparator terminal and a voltage representative of the threshold voltage value at a second comparator terminal. The comparator may provide at its output an output voltage representative of the result of the comparison, e.g. representative of whether the voltage value of the input voltage is greater than the threshold voltage value. For example, the output voltage of the comparator may assume a first logic value (e.g., a high value, e.g. a logic 1) if the voltage value of the input voltage is greater than the threshold voltage value. The output voltage of the comparator may assume a second logic value (e.g., a low value, e.g. a logic 0) if the voltage value of the input voltage is less than the threshold voltage value. In this configuration, the output of the comparator may be a control signal for the current source 118 to trigger the low current operation mode.

The overvoltage detection circuit 126 may be configured to determine whether the voltage value of the input voltage fulfills the overvoltage criterion based on the result of the comparison, e.g. based on the output of the comparator. For example, the overvoltage detection circuit 126 may determine that the voltage value of the input voltage fulfills the overvoltage criterion if the voltage value of the input voltage is greater than the threshold voltage value. Illustratively, the overvoltage detection circuit 126 may determine the occurrence of an overvoltage condition (and trigger the low current mode of the current source 118) if the comparator outputs a logic value indicative of the input voltage being greater than the threshold voltage.

The threshold voltage and the threshold voltage value may be selected according to circuit considerations, e.g. based on the specific properties of the circuit 100 and driver circuit 106. In general, the threshold voltage value may have any suitable value that may represent an overvoltage condition of the circuit if the input voltage becomes greater than such threshold. In an exemplary configuration, the threshold voltage value may be equal to or greater than the (maximum) operational voltage of the driver circuit 106. Only as a numerical example, the threshold voltage value may be in the range from 10 V to 30 V, for example in the range from 15 V to 25 V, for example the threshold voltage value may be 20 V or 25 V.

The use of a comparator and the triggering of the low current mode based on the comparison may be an approach that may be implemented in a simple and efficient manner, e.g. using analog components. It is however understood that also other mechanisms may be provided to evaluate whether the input voltage fulfills an overvoltage criterion. As another example, the overvoltage detection circuit 126 may evaluate a current value at the input terminal 108, e.g. by comparing the input current value with a threshold current value. As a further example, the overvoltage detection circuit 126 may evaluate a temperature of the driver circuit 106, e.g. a temperature at or around the input terminal 108, e.g. by comparing the temperature with a threshold temperature value. As a further example, the overvoltage detection circuit 126 may receive from another circuit an indication of an overvoltage condition, e.g. another circuit external to the driver circuit 106, for example a circuit coupled with the supply terminal 102 or a circuit monitoring the supply source.

The low current operation mode of the current source 118 may include the current source 118 generating less current compared to a normal (non-overvoltage) operation of the circuit 100, e.g. the low current operation mode of the current source 118 may include the current source 118 drawing less current from the input terminal 108. Illustratively, the overvoltage detection circuit 126 may trigger the low current operation mode and cause the current source 118 to draw less current from the input terminal 108 with respect to the current drawn prior to the occurrence of the overvoltage condition.

The low current operation mode may thus include the current source 118 drawing less current compared to the current drawn through the load 119 (and the series element(s) 120) when the circuit 100 (e.g., the driver circuit 106) is not in overvoltage. The reduction in drawn current ensures that the power dissipation at the series element 120 and at the current source 118 is not excessive even in presence of the high voltage at the input terminal 108. As will be discussed in further detail below, the amount of the reduction in current drawn by the current source 118 may be adapted depending on circuit considerations, e.g. based on power dissipation, discharge time for the capacitor 114, properties of the series element, etc. Only as a numerical example, the (second) current drawn by the current source 118 in the low current operation mode may be at least 10% less than the (first) current drawn by the current source 118 in the normal operation mode, for example at least 20% less, for example at least 50% less.

In a corresponding manner, the current value of the (second) current drawn by the current source 118 in the low current operation mode may be adapted depending on circuit considerations. Only as a numerical example, the current value of the current drawn by the current source 118 in the low current operation mode may be in the range from 100 mA to 500 mA, for example in the range from 200 mA to 400 mA. Various configurations of the current source 118 may allow such controlled reduction of the drawn current, and exemplary realizations will be discussed in relation to FIG. 2A and FIG. 2B.

In general, in a conventional configuration the driver circuit 106 may shut down almost completely upon detection of an overvoltage at the input terminal, e.g. by maintaining only a few mA to prevent a complete reset. In this case, only the few mA are available for discharging the capacitor 114. On the contrary, in the proposed approach the current source 118 may be maintained active to draw an amount of current that causes a rapid discharge of the damping capacitor 114. The low current operation mode may thus include the current source 118 drawing less current (illustratively, decreasing the current value of the drawn current) without causing an interruption of the drawing of current by the current source 118. Illustratively, the low current operation mode may include the current source 118 drawing less current while maintaining the drawn current above a current value that facilitates the discharge of the damping capacitor 114.

As mentioned, the low current operation mode may include the current source 118 drawing current with a reduced current value compared to the current drawn when the circuit 100 is not in overvoltage. The reduced current value may be adapted according to circuit considerations, and may be a fixed value or a dynamic value.

In a simple configuration, the reduced current value may be a predefined fixed value, to which the drawn current may be reduced upon occurrence of the overvoltage condition. In this scenario, the overvoltage detection circuit 126 may be configured to cause (e.g., instruct) the current source 118 to decrease the drawn current to the predefined fixed value for the duration of the overvoltage condition, e.g. until the input voltage becomes less than the threshold voltage value.

In a more complex but more flexible approach, the reduced current value may be dependent on the voltage value of the input voltage at the input terminal 108 when the voltage value is fulfilling the overvoltage condition (e.g., when the voltage value is above the threshold voltage value). Illustratively, the reduced current value for the drawn current may vary according to the voltage value of the input voltage. This configuration may allow a more efficient discharge of the damping capacitor 114, e.g. with an improved balance between power dissipation and discharge time. For example, the reduced current value may be higher at the beginning of the overvoltage condition when the voltage at the input terminal 108 is still increasing, and may be decreased to a lower current value upon the voltage at the input terminal 108 having reached a maximum value, and may be then increased to a higher current value upon the damping capacitor 114 being (partially) discharged and the input voltage decreasing to lower voltage values. This approach may thus ensure an overall constant power consumption while allowing a faster discharge of the capacitor 114 by drawing more current when the situation allows it.

The overvoltage detection circuit 126 may be configured (as part of the low current operation mode) to cause the current source 118 to draw current with a current value that depends on the voltage value of the input voltage. As an exemplary configuration, the overvoltage detection circuit 126 may be configured to cause the current source 118 to draw current with a first current value if the voltage value of the input voltage is in a first voltage range (e.g., greater than a first threshold voltage and less than a second threshold voltage). The overvoltage detection circuit 126 may be configured to cause the current source 118 to draw current with a second current value (lower than the first current value) if the voltage value of the input voltage is in a second voltage range (e.g., greater than the second threshold voltage and less than a third threshold voltage). The overvoltage detection circuit 126 may be configured to cause the current source 118 to draw current with a third current value (less than the second current value) if the voltage value of the input voltage is in a third voltage range (e.g., greater than the third threshold voltage), etc.

In some aspects, a clamping voltage value may be defined for the input voltage, such that in case of an overvoltage condition, when the input voltage raises above the clamping voltage value the current value of the drawn current may be maintained (illustratively, clamped) at a constant value. Illustratively, the overvoltage detection circuit 126 may be configured to cause the current source 118 to maintain the drawn current at a constant current value if the voltage value of the input voltage increases above a clamping voltage value. This approach may simplify the discharge process, without the need for further adapting the operation of the current source 118.

In a corresponding manner, a lower clamping voltage value may be defined for the input voltage, such that in case of an overvoltage condition when the input voltage falls below the lower clamping voltage value the current value of the drawn current may be maintained at a further (higher) constant value. Illustratively, the overvoltage detection circuit 126 may be configured to cause the current source 118 to maintain the drawn current at the further constant current value if the voltage value of the input voltage decreases below the lower clamping voltage value. This approach may simplify the final part of the discharge process, without the need for further adapting the operation of the current source 118 when the damping capacitor 114 has been already discharged for a certain period of time.

According to various aspects, the overvoltage detection circuit 126 may be configured to interrupt the low current operation mode if the input voltage stops fulfilling the overvoltage criterion, e.g. if the input voltage becomes less than the threshold voltage value. Illustratively, the overvoltage detection circuit 126 may be configured to cause the current source 118 to draw current with the normal current value for the operation of the circuit 100 (e.g., of the series element 120) as soon as the overvoltage detection circuit 126 no longer detects an overvoltage condition.

According to various aspects, the overvoltage detection circuit 126 may take into consideration further criteria in addition to the voltage value of the input voltage to decide whether to intervene and trigger the low current operation mode. The evaluation of further criteria may enhance the reliability and robustness of the proposed strategy, for example by ensuring that the overvoltage detection circuit 126 intervenes only when necessary, thus avoiding any “false positives” in relation to the overvoltage condition.

As an exemplary configuration, the overvoltage detection circuit 126 may be configured to trigger the low current operation mode of the current source 118 if the voltage value of the input voltage fulfills the overvoltage criterion at least for a predefined amount of time (different from 0 s), illustratively longer than an instantaneous determination of the voltage value. For example, the overvoltage detection circuit 126 may be configured to trigger the low current operation mode of the current source 118 if the voltage value of the input voltage is (and remains) greater than the threshold voltage value at least for a predefined amount of time. This approach may ensure that the low current operation mode is triggered only for “actual” overvoltage situations, and not for random fluctuations of the supply voltage 104. The predefined amount of time may be selected based on a tradeoff between the desired reaction time and the avoidance of false positives. As a numerical example, the predefined amount of time may be in the range from 20 μs (microseconds) to 1 ms (millisecond), for example in the range from 50 μs to 500 μs, for example in the range from 100 μs to 300 μs.

As an exemplary implementation, the overvoltage detection circuit 126 may include or may be coupled with a clock generator configured to generate a clock signal. The overvoltage detection circuit 126 may count a number of cycles of the clock signal starting from the time point at which the input voltage starts fulfilling the overvoltage condition to determine whether the predefined amount of time elapsed.

As another criterion, in addition or in alternative to the amount of time for which the input voltage fulfills the overvoltage criterion, the overvoltage detection circuit 126 may be configured to trigger the low current operation mode of the current source 118 based on a slew rate of the input voltage. The term “slew rate” may be used herein as commonly understood in the art to indicate a change or an electrical quantity (e.g., the input voltage at the input terminal 108) per unit of time. Illustratively, the velocity with which the input voltage (and accordingly the supply voltage 104) varies over time may prompt a different response. For example, in case of a slower variation (a low slew rate) a slower response may suffice, whereas in case of a faster variation (a high slew rate) a faster response may be required.

For example, the overvoltage detection circuit 126 may be configured to trigger the low current operation mode of the current source 118 if the input voltage fulfills the overvoltage criterion and further if the slew rate of the input voltage fulfills a slew rate criterion. As an example, the overvoltage detection circuit 126 may be configured to trigger the low current operation mode of the current source 118 if the input voltage fulfills the overvoltage criterion and further if the slew rate of the input voltage is equal to or greater than a slew rate threshold. In a corresponding manner, the overvoltage detection circuit 126 may be configured to refrain from triggering the low current operation mode of the current source 118 if the slew rate of the input voltage is less than the slew rate threshold (even in case the input voltage fulfills the overvoltage criterion). As an alternative, if the slew rate of the input voltage is less than the slew rate threshold the overvoltage detection circuit 126 may be configured to wait for a predefined waiting period prior to triggering the low current operation mode of the current source 118.

The slew rate threshold may be selected depending on circuit considerations, e.g. to provide a balance between a rapid response in case of overvoltage and to avoid intervening too quickly if not needed. As a numerical example, the slew rate threshold may be in the range from 1 V/s (Volt per second) to 20 V/s, for example in the range from 2 V/s to 10 V/s. As an exemplary implementation, the overvoltage detection circuit 126 may include or may be coupled with a differentiator configured to carry out a differentiation of the voltage at the input terminal 108 to derive the slew rate of the input voltage.

A further advantage of the strategy proposed herein is that the various parameters relevant for the discharging of the damping capacitor may be freely adapted and programmed, thus providing a flexible approach that may be tailored to specific circuit properties and to a specific application scenario. The various parameters defining the overvoltage criterion, the level at which the drawn current should be reduced, the parameters defining the slew rate, etc. may be programmed in the circuit 100 and may be varied from one circuit to another to adapt the reaction of the circuit to possible behaviors of the supply voltage (see also FIG. 5).

FIG. 1B and FIG. 1C illustrate further possible configurations 100b, 100c of the circuit 100, to show possible additional components that the circuit 100 may include. In more detail, FIG. 1B shows a configuration 100b in which the circuit 100 further includes a temperature detection circuit 128, and FIG. 1C shows a configuration 100c in which the circuit 100 further includes a control circuit 130 for controlling the external series element 124.

According to various aspects, as shown in FIG. 1B, the driver circuit 106 may further include a temperature detection circuit 128. The temperature detection circuit 128 may be configured to protect the driver circuit 106 in case the temperature of the driver circuit 106 increases to a level that could deteriorate or damage the components of the circuit. In the representation in FIG. 1B, the temperature detection circuit 128 is shown separate from the internal series element 122, to better illustrate the functionalities of the temperature detection circuit 128. It is however understood that the temperature detection circuit 128 may be part of the internal series element 122, illustratively as circuit component through which current may flow to allow the discharge of the damping capacitor 114.

In general, the temperature detection circuit 128 may be configured to sense the temperature of the driver circuit 106, e.g. the temperature at which the driver circuit 106 is operating, and may be configured to cause a shutdown of the driver circuit 106 if the sensed temperature fulfills an over-temperature criterion. In an exemplary configuration, the temperature detection circuit 128 may be configured to cause the shutdown of the driver circuit 106 if the sensed temperature is in a predefined temperature range, e.g. if the sensed temperature is greater than a threshold temperature.

The predefined temperature range and/or the threshold temperature may be adapted depending on circuit considerations, e.g. depending on the resistance to temperature of the circuit components. Only as a numerical example, the temperature range may be from 100° C. to 200° C., for example from 120° to 180° C. As a further numerical example, the threshold temperature may be 100° C., 155° C., 160° C., 170° C., or any suitable temperature value.

The temperature detection circuit 128 causing the shutdown of the driver circuit 106 may include the temperature detection circuit 128 causing an interruption of the operation of the driver circuit 106. For example, the temperature detection circuit 128 may transmit a shutdown signal to one or more components of the driver circuit 106 to instruct an interruption of the respective operation. The shutdown of the driver circuit 106 may involve any suitable component of the driver circuit 106, e.g., the current source 118, the digital processing circuit, the power management circuit, etc.

As an exemplary implementation, the temperature detection circuit 128 may include a temperature sensor configured to sense the temperature, and a processing circuit configured to receive the sensed temperature from the sensor and instruct the shutdown according to the sensed temperature. The temperature sensor may include, for example, a negative-temperature-coefficient thermistor, a positive-temperature-coefficient thermistor, or any suitable temperature sensitive component.

The temperature detection circuit 128 may thus provide a further layer of protection to the driver circuit 106 in addition to the overvoltage protection provided by the overvoltage detection circuit 126. In various aspects, the temperature detection circuit 128 may be hardwired, illustratively, the functionality of the temperature detection circuit 128 may be a permanent functionality of the driver circuit that cannot be altered by software.

According to various aspects, as shown in FIG. 1C, additionally or alternatively to the temperature detection circuit 128, the driver circuit 106 may further include a control circuit 130 configured to control the external series element 124. The control circuit 130 may be configured to control the operation of the external series element 124 including, e.g., a start of the operation, a duration of the operation, a stop of the operation, etc. In the representation in FIG. 1C, the control circuit 130 is shown separate from the internal series element 122, to better illustrate the functionalities of the control circuit 130. It is however understood that the control circuit 130 may be part of the internal series element 122, illustratively as circuit component through which current may flow to allow the discharge of the damping capacitor 114.

In an exemplary configuration, the control circuit 130 may be configured to control the external series element 124 as a function of the voltage value of the input voltage at the input terminal 108. Illustratively, when the input voltage is in the safe operational range (and does not fulfill the overvoltage criterion), the control circuit 130 may control the operation of the external series element 124 based on the received supply voltage 104 (as input voltage). This configuration may thus provide a flexible adaptation of the operation of the external series element 124 using as control parameter the voltage supplied to the driver circuit 106.

As an example, considering the scenario in which the external series element 124 includes a plurality of light emitting elements, e.g. a plurality of LEDs, the control circuit 130 may be configured to cause an activation of a number of light emitting elements as a function of the voltage value of the input voltage. Illustratively, the control circuit 130 may turn on a higher number of light emitting elements for higher voltage values of the input voltage. For example, the control circuit may turn on a first number of light emitting elements for a first voltage value of the input voltage, a second number of light emitting elements (greater than the first number) for a second voltage value of the input voltage (greater than the first voltage value), etc. As an exemplary configuration, to turn on a light emitting element the control circuit 130 may control a corresponding switch element, e.g. a transistor. The switch element associated with a light emitting element may selectively enable or disable a current flow through the light emitting element (illustratively, of the current generated/drawn by the current source 118).

As mentioned above, the protection circuit 110 may include further protection elements to enhance the safety of the circuit 100. In some aspects, the protection circuit 110 may thus include one or more further protection components, e.g. coupled in parallel with the damping capacitor 114. The one or more further protection components may in general be configured to limit a peak voltage value of the supply voltage 104. Illustratively, the one or more further protection components may be configured to act as a clamp for the supply voltage 104, to prevent transient voltages from passing through.

As an example, the protection circuit 110 may include a transient voltage suppression (TVS) diode in parallel with the damping capacitor 114, e.g. coupled between the supply terminal 102 and ground 116. As a further example, additionally or alternatively, the protection circuit 110 may include a voltage-dependent resistor in parallel with the damping capacitor 114, e.g. coupled between the supply terminal 102 and ground 116. In view of the proposed discharge method, the protection circuit 110 may in general be free of discrete components to facilitate the discharge of the damping capacitor 114, e.g. the protection circuit 110 may be free of a high voltage transistor (e.g., a high voltage NMOS). However, in some aspects, to further facilitate the capacitor discharge, the protection circuit 110 may include an analog discrete component, such as a high voltage transistor (e.g., a high voltage NMOS) in parallel with the damping capacitor 114, e.g. coupled between the supply terminal 102 and ground 116.

In principle, there may be various configuration possible for the current source 118 of the driver circuit 106. As a simple configuration, the current source 118 may include a current mirror, e.g. a cascode current mirror, and the low current operation mode may include varying (e.g., decreasing) an input current to the current mirror to obtain a corresponding variation of the output current of the current mirror. As a further exemplary configuration, the current source 118 may include an operational amplifier with a feedback loop, and the low current operation mode may include varying (e.g., decreasing) a reference current for the operational amplifier to obtain a corresponding variation of the output current of the operational amplifier. In a preferred configuration, the current source 118 may include a plurality of current sources, as discussed in further detail in relation to FIG. 2

FIG. 2 shows a current source 200 in a schematic representation, according to various aspects. The current source 200 may be an exemplary realization of the current source 118 of the driver circuit 106.

As shown, in various aspects the current source 200 may include a plurality of current sources, e.g. a main (or primary) current source 202 and one or more auxiliary (or secondary) current sources 204. In the exemplary representation in FIG. 2 a single auxiliary current source 204 is illustrated, but it is understood that the current source 200 may include any suitable number of auxiliary current sources, e.g. one, two, three, four, five, or more than five. In general, each current source 202, 204 may be configured to draw current from the input terminal 108 through the series element 120.

In an exemplary configuration, the current source 202, 204 may all participate in the normal operation of the driver circuit 106. Illustratively, when the input voltage does not fulfill the overvoltage condition, the driver circuit 106 may operate with its nominal current, and the sum of the currents drawn by the plurality of current source 202, 204 may define the nominal current of the driver circuit 106. In case of an overvoltage condition, one or more of the current sources 202, 204 may be turned off, to reduce the value of the drawn current. Illustratively, the low current operation mode may include the overvoltage detection circuit causing one or more of the plurality of current sources 202, 204 to stop drawing current from the input terminal 108.

For example, different current sources 202, 204 may be configured to draw a different current from the input terminal 108. As an example, a main current source 202 may be configured to draw more current than an auxiliary current source 204 (e.g., than each auxiliary current source 204). The low current operation mode may include selecting which of the current sources 202, 204 to maintain active and which current sources 202, 204 to deactivate depending on the voltage value of the input voltage. For example, when the voltage value is at its peak, or closer to its peak, the main current source 202 may be off, and the auxiliary current source 204 may be on, to allow a stronger reduction of the drawn current. When the voltage value starts decreasing, e.g. when the voltage value is at an intermediate value, the main current source 202 may be on, and the auxiliary current source 204 may be off, to allow a drawing more current.

In another exemplary configuration, the main current source 202 may be configured to draw current during a normal operation of the driver circuit, e.g. in case the input voltage at the input terminal does not fulfill overvoltage criterion. For example, the main current source 202 may be configured to draw current in case the voltage value of the input voltage is below the threshold voltage value. The auxiliary current source(s) 204 may be configured to draw current during an overvoltage condition of the driver circuit e.g. in case the input voltage at the input terminal fulfills overvoltage criterion. For example, the auxiliary current source(s) 204 may be configured to draw current in case the voltage value of the input voltage is greater than the threshold voltage value.

Illustratively, in this other configuration, the low current operation mode of the current source 200 may include turning off the main current source 202 and activating (only) the auxiliary current source(s) 204, e.g. one or more of the auxiliary current source(s) 204 depending on the desired current value for the drawn current. Further illustratively, the low current operation mode may include causing the main current source 202 to stop drawing current, and causing the auxiliary current source(s) 204 to start drawing current.

In general, the auxiliary current source(s) 204 may be configured to draw current with a lower current value compared to the main current source 202, thus avoiding an excessive power consumption while allowing the discharge of the damping capacitor. For example, in case the current source 200 includes a plurality of auxiliary current sources 204, the low current operation mode may include activating a number of auxiliary current sources 204 as a function of the voltage value of the input voltage. As another example, the low current operation mode may include activating different auxiliary current sources 204 that draw a different current as a function of the voltage value of the input voltage.

As an exemplary configuration, the low current operation mode may include activating a first auxiliary current source 204 drawing a first current if the voltage value of the input voltage is in a first voltage range (while maintaining the main current source 202 off). The low current operation mode may further include activating a second auxiliary current source 204 drawing a second current if the voltage value of the input voltage is in a second voltage range, etc. As another exemplary configuration, the low current operation mode may include activating a first number of auxiliary current sources 204 to draw a first current if the voltage value of the input voltage is in a first voltage range. The low current operation mode may further include activating a second number of auxiliary current sources 204 to draw a second current if the voltage value of the input voltage is in a second voltage range, etc.

The configuration with a plurality of current sources allows thus a flexible and efficient adaptation of the current to be generated/drawn in case of overvoltage, thus allowing a rapid and reliable discharge process for the damping capacitor.

FIG. 3A and FIG. 3B show a respective circuit 300a, 300b in a schematic representation, according to various aspects. The circuit 300a, 300b may be an exemplary realization of the circuit 100.

In general, the circuit 300a, 300b may include a supply terminal 302 to receive a supply voltage 304 (e.g., a battery voltage V_{BAT}). The circuit 300a, 300b may further include a driver circuit 306 (an exemplary realization of the driver circuit 106) with an input terminal 308 to receive the supply voltage 304 as input voltage. The circuit 300a, 300b may further include a protection circuit 310a, 310b disposed between the supply terminal 302 and the input terminal 308 to protect the driver circuit 306 from an undesired behavior of the supply voltage 304.

In the exemplary configuration in FIG. 3A, the protection circuit 310a may include a diode 312 (as filter element) to block a negative portion of the supply voltage 304, a damping capacitor 304, C_{FILT} coupled in parallel between the input terminal 308 and ground 316. The protection circuit 310a may further include a further diode 332 in parallel with the damping capacitor 314, as additional protection element to block residuals of the negative portion of the supply voltage 304.

In the exemplary configuration in FIG. 3B, the protection circuit 310b may include the diode 312 and the damping capacitor 314. The protection circuit 310b may further include a further protection element 334, e.g. a further diode, a TVS, a VDR, or the like. The protection circuit 310b may further include a high voltage transistor 336, e.g. a high voltage MOS (such as a NMOS), and a differentiator 338 configured to determine a variation of the supply voltage 304 over time, and generate a control signal for the transistor 336 based on the determined variation. The high voltage transistor 336 may provide a further discharge path for the damping capacitor 314 in case of overvoltage.

Turning now to the driver circuit 306, the driver circuit 306 may include, in addition to the input terminal 308, various further terminal for coupling with external circuit and components. For example, the driver circuit 306 may include one or more data terminals 340 for data transmission and reception. The data terminals 340 may include, for example, a chip select terminal, CS, to receive a chip select signal; a clock terminal, SCLK, to receive a clock signal, a multiple input single output, MISO, to receive data, and a multiple output single input, MOSI, to output data. As another example, the driver circuit 306 may include one or more test terminals 342 at which test signals may be provided to carry out a testing of the driver circuit 306, e.g. a testing of one or more components of the driver circuit 306. The driver circuit 306 may be coupled with ground 317.

The driver circuit 306 may further include a digital processing circuit 344 (a digital core) coupled with the data terminals 340 and configured to carry out digital processing, e.g. for selecting current levels for the operation of an external series element 324, to implement derating functions, to bypass part of the drivers, etc. For example, the digital processing circuit 344 may be coupled with a memory 358 configured to store instructions for the digital processing circuit 344. For example, the memory 358 may store data and parameters for an operation of the driving circuit 306. As an exemplary implementation, the memory 358 may be a one-time programmable (OTP) memory.

The driver circuit 306 may further include a reversal protection circuit 346 configured to protect the driver circuit 306 from reverse input voltage. Illustratively, the reversal protection circuit 346 may be configured to block a negative portion of the input voltage at the input terminal 308. Considering the scenario in which the circuit 300a, 300b is coupled with a battery as supply source, the reversal protection circuit 346 may be referred to as battery reversal. The driver circuit 306 may further include an overvoltage detection circuit 326, e.g. configured as the overvoltage detection circuit 126. Illustratively, the overvoltage detection circuit 326 may monitor the input voltage (e.g., as output by the reversal protection circuit 346) and control a current source 318 of the driver circuit 306 accordingly to trigger a low current operation mode and allow a discharge of the damping capacitor 314.

The driver circuit 306 may further include a power management circuit 350 coupled with the reversal protection circuit 346 and the overvoltage detection circuit 326. The power management circuit 350 may be configured to control an operation of the reversal protection circuit 346 and the overvoltage detection circuit 326, e.g. to adjust one or more operating parameters of such circuits. The power management circuit 350 may be further coupled with a further capacitor 352, C_{LDO}, disposed externally to the driver circuit 306. The further capacitor 352 may be referred to herein as low-dropout capacitor, C_{LDO}. The internal power management circuit 350 may be an internal low-dropout regulator to generate a fixed voltage independently of the input voltage, thus providing a controlled voltage value for powering the components that require a small supply voltage, or in general a smaller supply voltage than other components of the driver circuit 306.

Regarding temperature protection, the driver circuit 306 may include a temperature sensor 354 and a thermal shutdown circuit 356, e.g. an exemplary realization of the temperature detection circuit 128. The temperature sensor 354 may be configured to sense a temperature of the driver circuit 306, and the thermal shutdown circuit 356 may be a hardwired circuit configured to force a shutdown of the driver circuit 306 if the sensed temperature indicates an over-temperature condition, e.g. if the sensed temperature is greater than a threshold temperature. Additionally or alternatively, the driver circuit 306 may include an over-temperature protection circuit configured to instruct a shut down if the internal temperature of the driver circuit 306 exceeds the maximum safe operating temperature. With respect to the thermal shutdown circuit 356, the over-temperature protection circuit may operate at the digital/software level, e.g. the over-temperature protection circuit may send an over-temperature signal to the digital processing circuit 344 based on the temperature sensed by the temperature sensor 354. The over-temperature signal may instruct the digital processing circuit 344 to initiate a shutdown of the driver circuit 306. The over-temperature protection circuit may thus be another exemplary component for the temperature detection circuit 128.

The driver circuit 306 may further include a control circuit 330 configured to control the external series element 324. In the exemplary configuration in FIG. 3A and FIG. 3B, the external series element 324 coupled with the driver device 306 may include a plurality of light emitting diodes 360, e.g. four LEDs as an example. In this configuration the control circuit 330 may be referred to as LED control circuit, and may be configured to control a light emission of the LEDs. For example, the control circuit 330 may be configured to control a corresponding transistor 362 for each LED 360 to enable or disable the current flow through the LEDs 360. In some aspects, the control circuit 330 may be configured to enable a current flow through a number of LEDs 360 as a function of the voltage value of the supply voltage 304 (as input voltage). For example, the transistors 362 may be an example of internal series element of the driver circuit 306.

As discussed above, in a conventional configuration, during positive surge pulses the voltage present after the reverse protection (that blocks negative peaks), e.g. after the diode 312, and the damping capacity 314 tends to remain high, stressing or making the driver 306 not work due to the intervention of the overvoltage 348 or thermal protections 354, 356. Illustratively, the overvoltage comparator above the maximum operating V_{BAT} turns off the current of series of LEDs (I1) to avoid thermal damage to the device. In this condition, the discharge current of filter capacitor 314 is the constant absorption current (few mA) of internal blocks as power management 350, monitors 348 and digital block 344. During the surge pulses, the input voltage tends to follow the maximum V_{BAT} peak value, preventing the overvoltage and thermal protection circuits from being able to reset under normal operating conditions.

On the contrary, in the proposed approach, the filter capacitance 314 may be discharged using the current flowing through the series element, e.g. the external series element 324 (or internal series element), e.g. the series of LEDs 360 in the exemplary case of FIG. 3A and FIG. 3B. Illustratively, the current already drawn to power the LEDs is used to discharge the filter capacitor 314 charged by the surge pulses. A very fast discharge is possible because a voltage monitor 348 with a low propagation time is used and the cutting of the LED bias current is also very rapid. The current source 318 may be controlled to define the current level to use in the discharge. In the proposed approach, the current I1 drawn by the current source 318 is controlled by means of the overvoltage comparator (as part of the overvoltage detection circuit 348), avoiding complete switch-off during surge pulses. This makes it possible to decide (even programming the value from the digital) the discharge current using just the one that flows in the series of LEDs 360. The thermal circuit 354, 356 still acts as a further safety feature to switch off I1 if the temperature exceeds the maximum allowed. With the proposed configuration it is possible to have a fast discharge between two peaks of the surge pulses and to avoid that the external filtering circuit with the series diode (for the negative peaks) acts as a maintainer of the peak voltage.

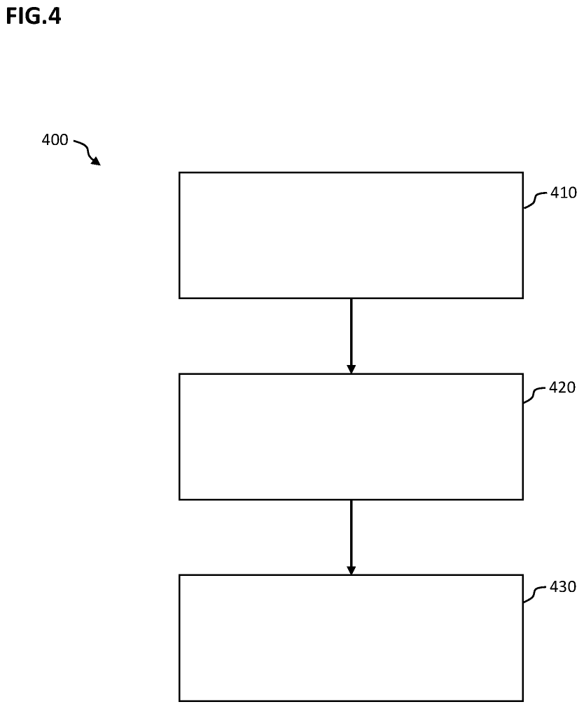

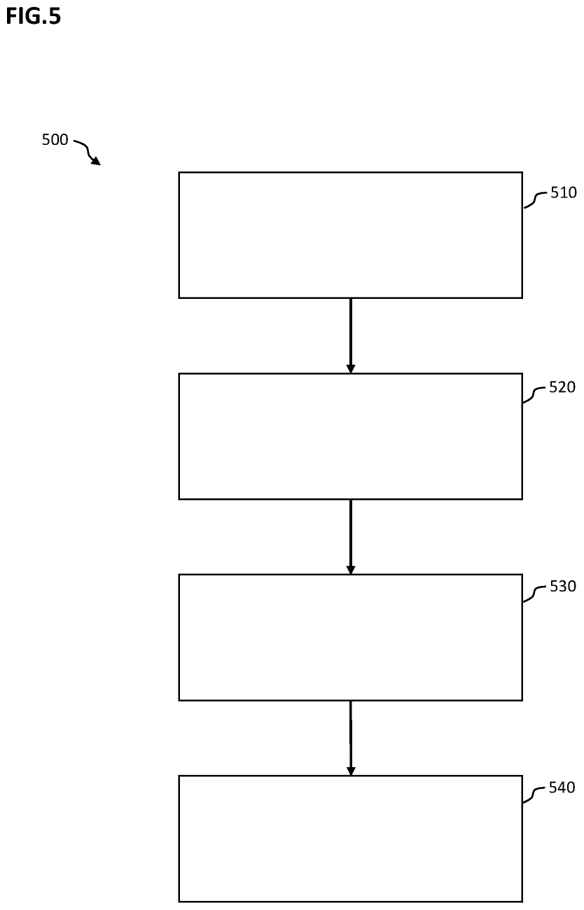

FIG. 4 shows a schematic flow diagram of a method 400 of discharging a damping capacitor, according to various aspects. It is understood that the aspects discussed in relation to the circuit 100, 300a, 300b may apply in a corresponding manner to the method 400, and vice versa.

The method 400 may include, in 410, determining (e.g., detecting, measuring, estimating, calculating) a voltage value of an input voltage at an input terminal of a driver circuit. The driver circuit may be configured as the driver circuit 106 in FIG. 1. For example, the input terminal of the driver circuit may be coupled with a supply terminal to receive a supply voltage as input voltage for powering an operation of the driver circuit.

The method 400 may further include, in 420, determining whether the voltage value of the input voltage fulfills an overvoltage criterion. For example, the method 400 may include determining whether the voltage value of the input voltage is greater than a threshold voltage value. As an exemplary configuration, the method 400 may include comparing the voltage value of the input voltage with the threshold voltage value, and determining whether the voltage value of the input voltage fulfills the overvoltage criterion based on the result of the comparison.

The method 400 may further include, in 430, if the voltage value of the input voltage fulfills the overvoltage criterion, triggering a low current operation mode of a current source of the driver circuit to allow a discharge of a damping capacitor coupled in parallel with the input terminal and ground through a load of the driver circuit coupled between the input terminal and ground, e.g., through a series element of the load, with the series element being coupled in series between the input terminal and ground. For example, the method 400 may include causing the current source to decrease the drawn current to allow a discharge of the damping capacitor through the load, e.g. through the series element, e.g. an internal series element and/or external series element of the driver circuit.

FIG. 5 shows a schematic flow diagram of a method 500 of programming a driver circuit for implementing a scheme for discharging a damping capacitor. It is understood that the aspects discussed in relation to the circuit 100, 300a, 300b may apply in a corresponding manner to the method 500, and vice versa.

The method 500 may include, in 510, causing an overvoltage condition of the driver circuit to determine a behavior of the driver circuit in case of overvoltage. For example, the method 500 may include providing to the driver circuit a supply voltage (e.g., as input voltage to an input terminal) having a voltage value greater than a specified operational voltage for the driver circuit. For example, the method 500 may include providing to the driver circuit a sequence of supply voltage pulses having a peak value greater than the specified operational voltage for the driver circuit, e.g. voltage pulses with a peak value of 120 V.

The method 500 may include, in 520, defining an overvoltage criterion for the driver circuit based on the behavior of the driver circuit in case of overvoltage. For example, the method 500 may include defining a threshold voltage indicative of an overvoltage condition of the driver circuit.

The method 500 may include, in 530, defining a current value for a current drawn by a current source of the driver circuit (through a series element) to allow a discharge of a damping capacitor coupled in parallel with the input terminal and ground through a load coupled between the input terminal and ground, e.g. through a series element of the load, with the series element being coupled in series between the input terminal and ground. For example, the method 500 may include defining a current value (or a plurality of current values) to be drawn by the current source in case of overvoltage to facilitate the discharge of the damping capacitor. For example, the method 500 may include defining a current value (or a plurality of current values) based on a target speed of the discharging.

The method 500 may include, in 540, programming the driver circuit using the defined overvoltage criterion and current value. For example, the method 500 may include programming an overvoltage detection circuit of the driver circuit with the overvoltage criterion, and programming the current source of the driver circuit with the defined current value.

The terms “processor”, “processing circuit”, or “control circuit” as used herein may be understood as any kind of technological entity that allows handling of data. The data may be handled according to one or more specific functions that the processor/processing circuit/control circuit may execute. Further, a processor/processing circuit/control circuit as used herein may be understood as any kind of circuit, e.g., any kind of analog or digital circuit. A processor/processing circuit/control circuit may thus be or include an analog circuit, digital circuit, mixed-signal circuit, logic circuit (e.g., a hard-wired logic circuit or a programmable logic circuit), microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. It is understood that any two (or more) of the processors/processing circuits/control circuits detailed herein may be realized as a single entity with equivalent functionality or the like, and conversely that any single processor/processing circuit/control circuit detailed herein may be realized as two (or more) separate entities with equivalent functionality or the like.

The term “connected” may be used herein with respect to terminals, integrated circuit elements, devices, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, devices, regions, contacts, etc., may be understood as an electrically conductive connection with, for example, ohmic behavior, e.g. provided by a metal or degenerate semiconductor in absence of p-n junctions in the current path. The term “electrically conductively connected” may be also referred to as “galvanically connected”. The term “coupled” may be used herein in the same manner as the term “connected”.

The term “terminal” may be used herein to describe a location (e.g., a point) or structure of a device or of an element of the device at which a signal (e.g., an analog signal, for example a current or a voltage) may be provided and/or to which another device or element may be connected. Illustratively, a terminal may be a location or a structure that is electrically conductively connected with the device or the element. A terminal may also be referred to herein as port, pin, contact, or contact point.

The word “exemplary” is used herein to mean “serving as an example, instance, or illustration”. Any embodiment or design described herein as “exemplary” is not necessarily to be construed as preferred or advantageous over other embodiments or designs.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

All acronyms defined in the above description additionally hold in all claims included herein.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

### LIST OF REFERENCE SIGNS

314 Damping capacitor
316 Ground terminal
100 Circuit 317 Ground terminal
100b Circuit configuration 318 Current source
100c Circuit configuration 324 External series element
102 Supply terminal 326 Overvoltage detection circuit
104 Supply voltage 330 Control circuit
106 Driver circuit 332 Diode
108 Input terminal 334 Protection element
110 Protection circuit 336 High voltage transistor
112 Filter element 338 Differentiator
114 Damping capacitor 340 Data terminals
116 Ground terminal 342 Test terminals
117 Ground terminal 344 Digital processing circuit
118 Current source 346 Reversal protection circuit
119 Load 348 Overvoltage detection circuit
120 Series element 350 Power management circuit
122 Internal series element 352 Capacitor
124 External series element 354 Temperature sensor
126 Overvoltage detection circuit 356 Thermal shutdown circuit
128 Temperature detection circuit 358 Memory
130 Control circuit 360 Light emitting diode
200 Current source 362 Transistor
202 Main current source 400 Method
204 Auxiliary current source 410 Method step
300a Circuit 420 Method step
300b Circuit 430 Method step
302 Supply terminal 500 Method
304 Supply voltage 510 Method step
306 Driver circuit 520 Method step
308 Input terminal 530 Method step
310a Protection circuit 540 Method step
310b Protection circuit
312 Diode

1. A circuit, comprising:
a supply terminal configured to receive a supply voltage;
a driver circuit comprising:
an input terminal coupled with the supply terminal to receive the supply voltage as input voltage for powering an operation of the driver circuit; and
a current source configured to draw current from the input terminal through a load coupled between the input terminal and ground,
wherein the load comprises a series element coupled in series between the input terminal and ground; and
a damping capacitor coupled in parallel with the input terminal and ground such that the damping capacitor is charged by the supply voltage;
wherein the driver circuit further comprises an overvoltage detection circuit configured to:
determine a voltage value of the input voltage at the input terminal; and
if the voltage value of the input voltage fulfills an overvoltage criterion, trigger a low current operation mode of the current source to allow a discharge of the damping capacitor through the series element.

2. The circuit according to claim 1, further comprising:
a filter element coupled between the supply terminal and the input terminal and configured to block a negative portion of the supply voltage.

3. The circuit according to claim 1,
wherein the series element comprises an internal series element disposed internally to the driver circuit and/or an external series element disposed externally to the driver circuit.

4. The circuit according to claim 1,
wherein the low current operation mode comprises the overvoltage detection circuit being configured to cause the current source to draw less current from the input terminal with respect to the current drawn prior to the voltage value of the input voltage fulfilling the overvoltage criterion.

5. The circuit according to claim 4,
wherein the low current operation mode comprises the overvoltage detection circuit being configured to cause the current source to draw less current from the input terminal without causing an interruption of the drawing of current by the current source.

6. The circuit according to claim 1,
wherein the overvoltage detection circuit is configured to trigger the low current operation mode of the current source if the voltage value of the input voltage fulfills the overvoltage criterion at least for a predefined amount of time.

7. The circuit according to claim 1,
wherein the overvoltage detection circuit is configured to trigger the low current operation mode of the current source if the voltage value of the input voltage fulfills the overvoltage criterion and further if a slew rate of the input voltage fulfills a slew rate criterion.

8. The circuit according to claim 1,
wherein, to determine whether the voltage value of the input voltage fulfills the overvoltage criterion, the overvoltage detection circuit is configured to:
compare the voltage value of the input voltage with a predefined threshold voltage value; and
determine that the voltage value of the input voltage fulfills the overvoltage criterion if the voltage value of the input voltage is greater than the threshold voltage value.

9. The circuit according to claim 8,
wherein the threshold voltage value is equal to or greater than a maximum rated operational voltage of the driver circuit.

10. The circuit according to claim 8,
wherein the low current operation mode comprises the overvoltage detection circuit being configured to:
cause the current source to draw current with a first current value if the voltage value of the input voltage is greater than a first threshold voltage and less than a second threshold voltage; and
cause the current source to draw current with a second current value less than the first current value if the voltage value of the input voltage is greater than the second threshold voltage.

11. The circuit according to claim 1,
wherein the current source comprises a plurality of current sources,
wherein each current source of the plurality of current sources is configured to draw current from the input terminal through the load, and
wherein the low current operation mode comprises the overvoltage detection circuit being configured to cause one or more current sources of the plurality of current sources to stop drawing current from the input terminal.

12. The circuit according to claim 3,
wherein the external series element comprises a plurality of light emitting elements coupled in series with one another.

13. The circuit according to claim 12,
wherein the plurality of light emitting elements comprises at least one light emitting diode.

14. A method of discharging a damping capacitor, the method comprising:
determining a voltage value of an input voltage at an input terminal of a driver circuit;
determining whether the voltage value of the input voltage fulfills an overvoltage criterion; and
if the voltage value of the input voltage fulfills the overvoltage criterion, triggering a low current operation mode of a current source of the driver circuit to allow a discharge of a damping capacitor coupled in parallel with the input terminal and ground through a load coupled between the input terminal and ground,
wherein the load comprises a series element coupled in series between the input terminal and ground.

15. A method of programming a driver circuit for discharging a damping capacitor, the method comprising:
causing an overvoltage condition of the driver circuit to determine a behavior of the driver circuit in case of overvoltage,
wherein causing the overvoltage condition of the driver circuit comprises providing an input voltage at an input terminal of the driver circuit having a voltage value greater than an operational voltage of the driver circuit;
defining an overvoltage criterion for the driver circuit based on the behavior of the driver circuit in case of overvoltage;
defining a current value for a current drawn by a current source of the driver circuit to allow a discharge of a damping capacitor coupled in parallel with the input terminal and ground through a load coupled between the input terminal and ground, wherein the load comprises a series element coupled in series between the input terminal and ground; and
programming the driver circuit using the defined overvoltage criterion and the defined current value.

16. The method according to claim 14,
wherein the series element comprises an internal series element disposed internally to the driver circuit and/or an external series element disposed externally to the driver circuit.

17. The method according to claim 14,
wherein the low current operation mode comprises the current source drawing less current from the input terminal with respect to the current drawn prior to the voltage value of the input voltage fulfilling the overvoltage criterion

18. The method according to claim 14,
wherein the low current operation mode comprises the current source drawing less current from the input terminal without causing an interruption of the drawing of current by the current source.

19. The method according to claim 14, wherein the method comprises triggering the low current operation mode of the current source if the voltage value of the input voltage fulfills the overvoltage criterion at least for a predefined amount of time.

20. The method according to claim 14, wherein the method comprises triggering the low current operation mode of the current source if the voltage value of the input voltage fulfills the overvoltage criterion and further if a slew rate of the input voltage fulfills a slew rate criterion.
